(19) United States
(12) Patent Application Publication
(10) Pub. No.: US 2009/0272428 A1
(43) Pub. Date: Nov. 5, 2009

(54) Insulating Glass Unit with Integrated Mini-Junction Device

(75) Inventors: Kai Wm. JANSEN, Lawrenceville, NJ (US); Anthony VARVAR, Mercerville, NJ (US); Kathryn A. CARRIGAN, Robbinsville, NJ (US); Hermann VOLLTRAUER, Monroe Township, NJ (US)

Correspondence Address: STERNE, KESSLER, GOLDSTEIN & FOX P.L.L.C., 1100 NEW YORK AVENUE, N.W., WASHINGTON, DC, 20005, US

(73) Assignee: EPV Solar, Inc., Robbinsville, NJ (US)

(21) Appl. No.: 12/395,889

(22) Filed: Mar. 2, 2009

Related U.S. Application Data
(60) Provisional application No. 61/196,700, filed on Feb. 28, 2008.
(60) Provisional application No. 61/196,701, filed on Feb. 28, 2008.
(60) Provisional application No. 61/196,702, filed on Apr. 29, 2008.
(60) Provisional application No. 61/196,703, filed on Apr. 29, 2008.
(60) Provisional application No. 61/196,704, filed on Apr. 29, 2008.

(51) Int. Cl. H01L 31/048; H01L 31/042

(52) U.S. Cl. 136/251; 136/244

(57) ABSTRACT

An insulating glass unit (IGU) is provided that includes a first substrate and a second substrate. The first and second substrates are spaced apart and substantially parallel to each other. The two substrates are hermetically sealed. A mini-junction device is positioned between the two substrates. The mini-junction device is at an edge of the two substrates without extending beyond their periphery. The mini-junction device houses an electrical coupling between a pair of wires and a pair of leads. A first end and the pair of wires and a first end of the pair of leads are coupled together. A second end of the pair of wires extends beyond the periphery of the substrates. A second end of the pair of leads extends through the first substrate. The IGU also includes a photovoltaic module coupled to the first substrate and electrically coupled to the second end of the pair of leads.

### CROSS REFERENCE TO RELATED APPLICATIONS

The present application claims the benefit of U.S. Provisional Patent Application No. 61/196,700, filed on Feb. 28, 2008, entitled “IGU with Edge Connector” by Jansen et al., U.S. Provisional Patent Application No. 61/196,701, filed on Feb. 28, 2008, entitled “Photovoltaic Panel with Edge Connector” by Jansen et al., U.S. Provisional Patent Application No. 61/196,702, filed on Apr. 29, 2008, entitled “BIPV Windows and Mounting Structures” by Jansen et al., U.S. Provisional Patent Application No. 61/196,703, filed on Apr. 29, 2008, entitled “Photovoltaic Panels with Edge Connectors and Mounting Structure” by Jansen et al., and U.S. Provisional Patent Application No. 61/196,704, filed on Apr. 29, 2008, entitled “Photovoltaic Panel Etching and Edge Connector” by Jansen et al., which are incorporated herein by reference in their entirety.

### BACKGROUND OF THE INVENTION

1. Field of the Invention

This invention relates generally to insulating glass units containing photovoltaic modules.

2. Description of the Related Art

Solar cells and other photovoltaic devices convert visible light and other solar radiation into usable electrical energy. The energy conversion occurs as the result of the photovoltaic effect. Solar radiation (sunlight) impinging on a photovoltaic device and absorbed by an active region of semiconductor material, e.g. an intrinsic i-layer of amorphous silicon, generates electron-hole pairs in the active region. The electrons and holes are separated by an electric field of a junction in the photovoltaic device. The separation of the electrons and holes by the junction results in the generation of an electric current and voltage. The electrons flow toward the region of the semiconductor material having a n-type conductivity. The holes flow toward the region of the semiconductor material having a p-type conductivity. Current will flow through an external circuit connecting the n-type region to the p-type region as long as light continues to generate electron-hole pairs in the photovoltaic device.

Amorphous single-junction devices are comprised of three layers. These are p-and n-layers which are extrinsic or doped and i-layer which is intrinsic or undoped (at least containing no intentional doping). The i-layer is much thicker than the doped layers. This is because mainly light absorbed in the i-layer is converted to electrical power which can be used in an external circuit. The thickness of the i-layer (sometimes called the absorber layer) determines how much light is absorbed. When a photon of light is absorbed in the i-layer it gives rise to a unit of electrical current (an electron-hole pair). However, this electrical current will go nowhere on its own. Hence, the p- and n-layers. These layers, which contain charged dopant ions, set up a strong electric field across the i-layer. It is this electric field which draws the electric charge out of the i-layer and sends it through an external circuit where it can provide power for electrical components.

Thin film solar cells are typically constructed of a semiconductor-containing film on a substrate, such as amorphous silicon. The substrate of the solar cell can be made of glass or a metal, such as aluminum, niobium, titanium, chromium, iron, bismuth, antimony or steel. Soda-lime glass is often used as a substrate because it is inexpensive, durable and transparent. If a glass substrate is used, a transparent conductive coating, such as tin oxide, can be applied to the glass substrate prior to forming the semiconductor-containing film. A metallic contact can be formed on the back of the solar cell. Solar cells are often placed in metal frames to provide attractive photovoltaic modules.

Over the years numerous solar cells have been developed which have met with varying degrees of success. Single junction amorphous silicon solar cells are useful but often cannot achieve the power and conversion efficiency of multi-junction solar cells. Multi-junction solar cells can be constructed of various materials which are able to capture and convert a wider portion of the solar spectrum into electricity. Multi-junction solar cells have been produced with amorphous silicon and its alloys, such as hydrogenated amorphous silicon carbon and hydrogenated amorphous silicon germanium, with wide and low bandgap intrinsic i-layers. Multi-junction amorphous silicon solar cells with the same bandgap materials in both junctions typically have a relatively high open circuit voltage and low current; they normally capture and convert into electricity wavelengths of sunlight between 400 to 900 nanometers (nm) of the solar spectrum.

An amorphous silicon solar cell is comprised of a body of hydrogenated amorphous silicon (a-Si:H) material, which can be formed in a glow discharge of silane. Within the body of the cell there is an electric field which results from the different dopant types of the semiconductor regions comprising the body.

Amorphous silicon solar cells are often fabricated by the glow discharge of silane. The process of glow discharge involves the discharge of energy through a gas at relatively low pressure and high temperature in a partially evacuated chamber. A typical process for fabricating an amorphous silicon solar cell comprises placing a substrate on a heated element within a vacuum chamber. While silane, at low pressure, is admitted into the vacuum chamber, a glow discharge is established between two electrodes and an amorphous silicon film deposits upon the substrate. The segments, layers or cells of multi-junction solar cells are electrically interconnected, such as by laser scribing.

Solar panels with insulating glass units (IGUs) have been developed for a variety of different building structures. IGUs contain photovoltaic devices that can produce electricity from sunlight.

IGUs are becoming more and more highly regarded as a key ingredient in green building design and are in increasing demand by architects throughout the world. IGUs are particularly suitable in window openings where the ability to impart transparency to the solar module provides wide architectural flexibility by allowing light in, yet creating solar electricity simultaneously. However, conventional IGUs are often coupled with connectors such as junction boxes that interfere with mounting the IGUs to building structures. Conventional IGUs often have current leakage problems and can not provide proper electrical isolation. This will limit the applications of IGUs in green building constructions.

### SUMMARY OF THE INVENTION

In one embodiment, a solar panel including an insulating glass unit (IGU) is provided. The IGU has a low profile connector near the periphery of the IGU. In another embodiment, a solar panel including an array of IGUs and an exterior frame is provided. The IGUs are positioned within the exterior frame. Each IGU includes a first substrate and a second substrate, a mini-junction device, and a photovoltaic module. The second substrate is substantially parallel to the first substrate. The two substrates are spaced apart and hermetically sealed. The mini-junction device is positioned between the two substrates. The mini-junction device is at the edge of the two substrates and does not extend beyond the periphery of the two substrates. The mini-junction device houses an electrical coupling between a first end of a pair of wires and a first end of a pair of leads. A second end of the pair of wires extends beyond the periphery of the two substrates. A second end of the pair of leads extends through the first substrate. The photovoltaic module is coupled to the first substrate. The photovoltaic module is also coupled to the second end of the pair of leads.

Further embodiments, features, and advantages of the invention, as well as the structure and operation of the various embodiments of the invention are described in detail below with reference to accompanying drawings.

### BRIEF DESCRIPTION OF THE DRAWINGS

Embodiments of the invention are described with reference to the accompanying drawings. In the drawings, like reference numbers may indicate identical or functionally similar elements. The drawings in which an element first appears is generally indicated by the left-most digit in the corresponding reference number.

FIG. 1A illustrates a front view of an insulating glass unit (IGU) according to one embodiment of the present invention.

FIG. 1B illustrates a side view of the IGU in FIG. 1A according to one embodiment of the present invention.

FIG. 1C illustrates an exemplary solar panel that contains two IGUs according to one embodiment of the present invention.

FIG. 2A illustrates an exemplary structure of a photovoltaic module used in an IGU according to one embodiment of the present invention.

FIG. 2B illustrates an exemplary structure of a photovoltaic module with an etching used in an IGU according to one embodiment of the present invention.

FIG. 3A illustrates an exemplary structure of a semiconductor used in a photovoltaic module according to one embodiment of the present invention.

FIG. 3B illustrates another exemplary structure of a semiconductor used in a photovoltaic module according to one embodiment of the present invention.

FIG. 4 illustrates an exemplary structure of a photovoltaic module with two p-n-i junction cells according to one embodiment of the present invention.

FIG. 5 illustrates an exemplary procedure that can be used to produce an IGU in one embodiment of the present invention.

FIGS. 6a through 6f illustrate laser scribing steps that can be used in one embodiment of the present invention.

### DETAILED DESCRIPTION OF THE INVENTION

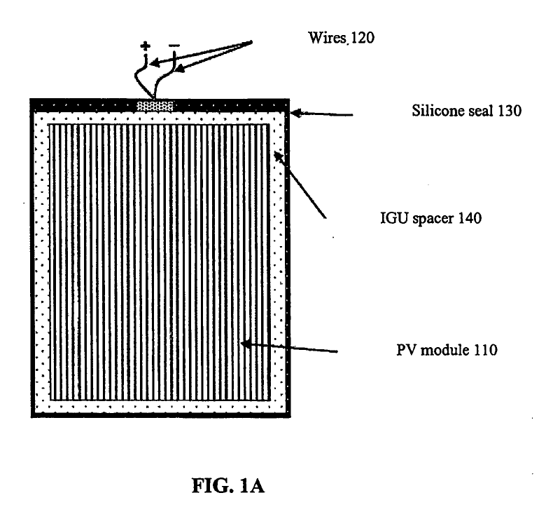

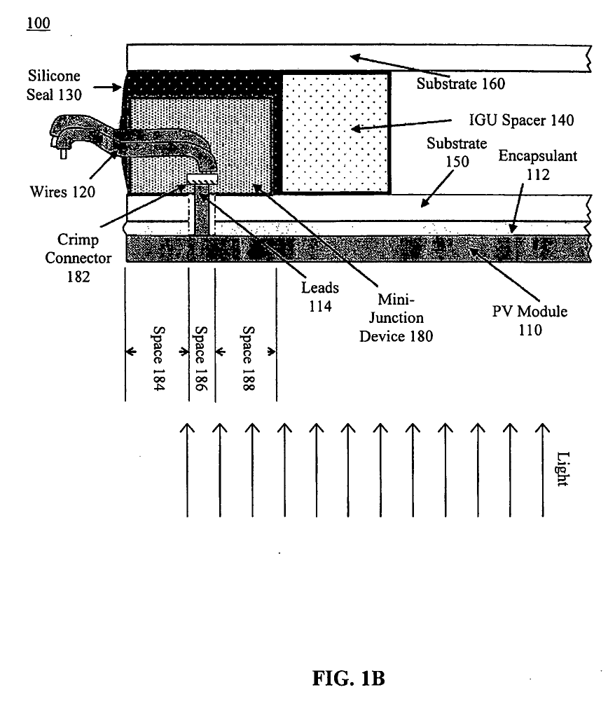

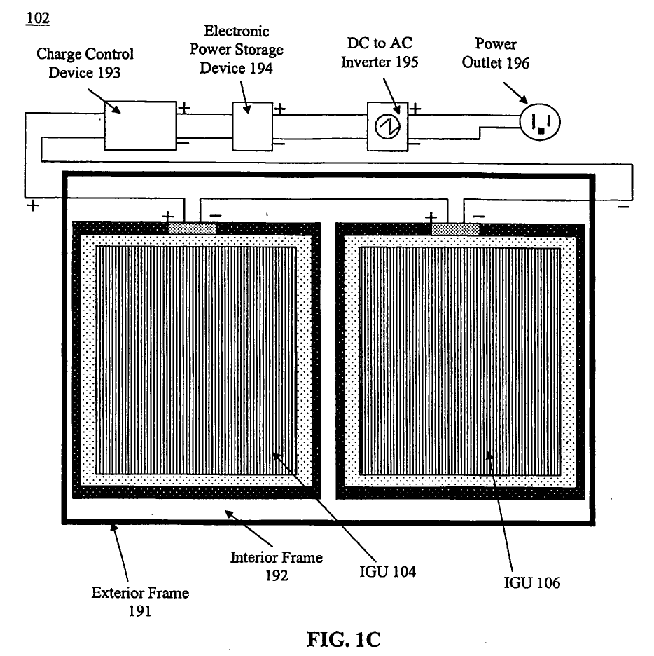

Referring to FIGS. 1A and 1B, a front view and a side view of an exemplary insulating glass unit (IGU) 100 is illustrated according to one embodiment of the present invention. One or more such IGUs can be used in a solar panel. According to one feature of the present invention, IGU 100 satisfies the requirements specified in UL 1703, Standard for Safety Flat-Plate Photovoltaic Modules and Panels. IGU 100 can aslo provide proper electrical isolation without current leakage. With a low-profile mini-junction device, IGU 100 is an ideal candidate that can be used in solar panels for green building construction. In some embodiments, an etching in a semiconductor in IGU 100 can have a variety of aesthetic and functional features.

In FIG. 1A, IGU 100 includes a photovoltaic (PV) module 110, a pair of wires 120, a silicone seal 130, and an insulating glass unit (IGU) spacer 140. FIG. 1B illustrates a side view of IGU 100.

Referring to FIG. 1B, one embodiment of an IGU 100 includes a first substrate 150, a second substrate 160, and a mini-junction device 180. First substrate 150 and second substrate 160 are parallel to each other. An IGU spacer 140 is placed between substrate 150 and 160 to space them apart. Spacer 140 can include a desiccant.

Mini-junction device 180 is placed between first substrate 150 and second substrate 160. Mini-junction device 180 is positioned at an edge of the two substrates without extending beyond a periphery of substrates 150 and 160. Mini-junction device 180 has a pair of wires 120. One end of wires 120 is coupled to an end of a pair of leads 114. An encapsulant 112 is positioned to environmentally seal the IGU 100. The encapsulant 112 includes an aperture with a space 186 such that the end of leads 114 extends from the aperture. Mini-junction device 180 is sealed between substrates 150 and 160 by a silicone seal 130 and has a total width of spaces 184, 186 and 188.

In one embodiment, encapsulant 112 can be made of a polymer and a moisture barrier. Examples of suitable polymers for the encapsulant include but are not limited to, ethylene vinyl acetate (EVA), polyvinyl acetate (PVA), PVB, TEDLAR type plastic, NUVA-SIL type plastic, TEFZEL type plastic, ultraviolet curable coatings, combinations thereof and the like. The moisture barrier can be made of glass or be a multi-layer structure such as a plastic surround a metal film such as aluminum and the like.

In one embodiment, mini-junction device 180 is configured to withstand at least twice the voltage of the IGU 100 plus 1000 volts. Mini-junction device 180 has a low profile that is lower than a width of spacer 140. By way of illustration, and without limitation, the mini-junction device 180 has a profile that is less than, 2.0 inches, 1.5 inches, 1.0 inch, 0.5 inches and the like. The mini-junction device 180 has a profile low enough so that it does not interfere with associated mounting structures of IGU 100. Mini-junction device 180 can include a potting material. In one embodiment, mini-junction device 180 satisfies the requirements specified in UL 1703. UL 1703 is a standard for flat-plate photovoltaic modules and panels. This standard is maintained by Underwriters Laboratories Inc. of Northbrook, Ill.

FIG. 1C illustrates an exemplary structure of a solar panel 102 according to one embodiment of the present invention. Solar panel 102 includes an exterior frame 191 defining the exterior perimeter of solar panel 102. IGUs 104 and 106 are positioned within exterior frame 191. Each IGU is defined at least in part by an interior frame 192. At least a portion of each IGU is a photovoltaic device with a mini-junction device, as discussed above, positioned adjacent to a periphery of a substrate of the insulating glass unit without extending beyond the periphery, the mini-junction device including wire leads coupled to metallic foil strips.

As illustrated in FIG. 1C, a charge control device 193 is also provided. An electrical power storage device 194, a DC to AC inverter 195, and a power outlet 196 are also provided.

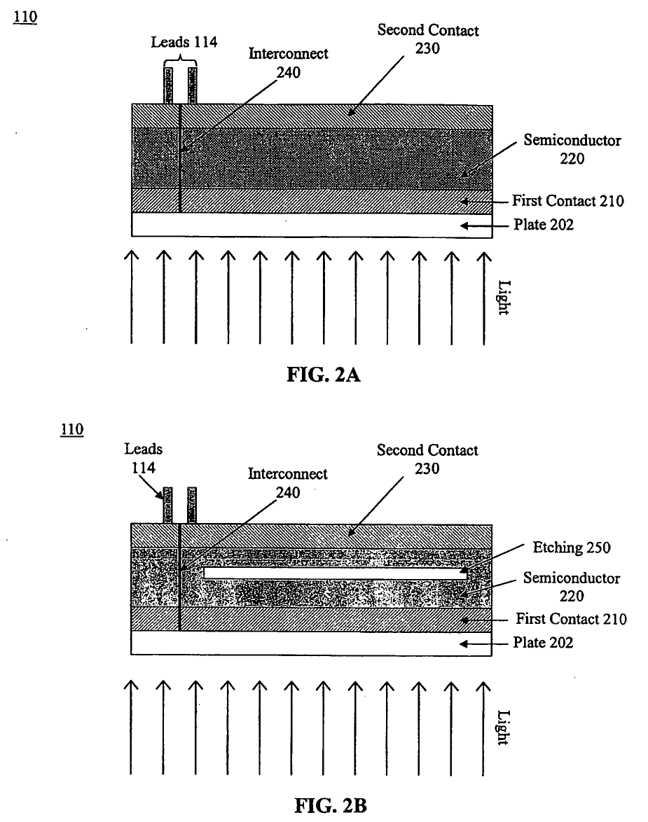

IGU 100 also includes a PV Module 110 facing a direction where the light comes from. FIG. 2A illustrates an exemplary structure of PV module 110 according to one embodiment of the present invention. In FIG. 2A, PV module 110 includes a plate 202, a first contact 210, a semiconductor 220, and a second contact 230. Semiconductor 220 is adjacent to first contact 210. Second contact 230 is adjacent to semiconductor 220. An interconnect 240 is formed between first and second contacts 210 and 230. Leads 114 are coupled to second contact 230. In one embodiment, leads 114 can be metallic foil strips.

FIG. 2B illustrates an embodiment in which semiconductor 220 includes an etching 250. Referring to FIG. 2B, PV module 110 can include a plate 202, a first contact 210, and a second contact 230. PV module 110 also includes a semiconductor 220 with an etching 250 formed in semiconductor 220. Etching 250 can be formed by removing portions of semiconductor 220. Etching 250 can have a variety of aesthetic and functional features, including but not limited to, an etch that increases the transparency of the module; etching in such a manner as to create dots, stripes, patterns, letters, logos, murals, and other artistic designs in the module; an etch that maintains the module's ability to be used as a photovoltaic device; an etch that is capable of modifying the module's electrical performance and the like.

Semiconductor 220 can be, CdS, In₁_{_{—x}}GaₓN alloy as disclosed in U.S. Pat. No. 4,233,085; In₁_{_{—x}}GaₓN alloy (Indium, Gallium, and Nitrogen) as disclosed in U.S. Pat. No. 7,217,882; a Cd(Se,Te) Alloy as disclosed in U.S. Pat. No. 4,296,188; silicon 51-88% lithium 3-30% alumina 0.5-29% fluorine 0.5-8% hydrogen 1-12% vanadium 0-5% as disclosed in U.S. Pat. No. 4,633,031, silicon 51-88% lithium 3-30% alumina 0.5-29% fluorine 0.5-8% hydrogen 0.5-12% antimony 0.01-20% Cobalt 0.01-6% as disclosed in U.S. Pat. No. 4,633,031; a silicon-germanium alloy as disclosed in U.S. Pat. No. 4,609,771, silicon alloy materials, germanium alloy materials, silicon-germanium alloy materials, cadmium telluride, cadmium selenide, gallium arsenide, and copper indium diselenide as disclosed in U.S. Pat. No. 4,713,492; copper-indium-gallium-diselenide (Culnₓ Ga₁_{_{—x}} Se_{0.2} or just CIGS; mercury cadmium telluride (Hg Cd/Te) as disclosed in U.S. Pat. No. 3,638,026; Pbₓ Cd(₁_{_{—}}x) S (lead-cadmium-sulphide) alloy as disclosed in U.S. Pat. No. 4,529,832; Cd₁_{_{—x}} Znₓ Te, CdTe.sub.11 S_{y}, CdTe₁_{_{—y}} S_{y} as disclosed in U.S. Pat. No. 4,568,792; silicon, germanium, indium phosphide, gallium arsenide, aluminum antimonide, gallium phosphide, gallium antimonide, cadmium sulfide, cadmium sellinide, cadmium telluride, zinc oxide, zinc sulfide, zinc sellinide, cupric sulfide, cupric oxide, titanium dioxide, aluminum arsenide, and gallium aluminum arsenide as disclosed in U.S. Pat. No. 3,978,333, and the like. The above mentioned patents are incorporates by reference herein in their entirety.

In various embodiments, semiconductor 220 is an amorphous silicon-containing material. Suitable semiconductor materials include but are not limited to, hydrogenated amorphous silicon, hydrogenated amorphous silicon carbon, hydrogenated amorphous silicon germanium and the like. Semiconductor 220 can be a single, tandem or triple junction cell with p₁i₁n₁, p₁i₁n₁ and p₂i₂n₂, and p₁i₁n₁, p₂i₂n₂, and p₃i₃n₃ cells respectively.

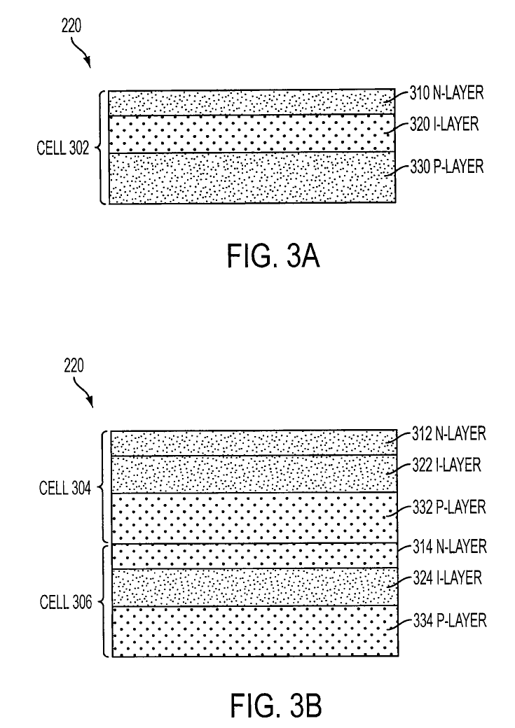

In the embodiment where IGU 100 includes a single junction solar cell, semiconductor 220 is a p-i-n or an n-i-p amorphous silicon semiconductor. An exemplary single cell semiconductor is illustrated in FIG. 3A. In FIG. 3A, semiconductor includes a single junction solar cell 302. Cell 302 includes a n-layer 310, an i-layer 320, and a p-layer 330. Semiconductor 220 can be hydrogenated amorphous silicon, hydrogenated amorphous silicon carbon or hydrogenated amorphous silicon germanium. The positively doped (p-doped) amorphous silicon p-layer of the amorphous silicon semiconductor is positioned, disposed and deposited on, covers, lies upon, and is connected to the front contact. The p-layer can be positively doped with diborane (B₂H₆), BF₃, trimethylboron (TMB) or other boron-containing compounds. An amorphous silicon, undoped, active intrinsic i-layer is deposited upon, positioned between and connected to the p-layer and a negatively doped (n-doped) amorphous silicon n-layer. The n-layer is positioned on the i-layer and can be amorphous silicon carbon or amorphous silicon negatively doped with phosphine (PH3) or some other phosphorous-containing compound.

Amorphous silicon can be doped by adding impurities to silane. By way of illustration, and without limitation, a first dopant can be diborane (B₂H₆), which is added to the silane to form a p-type amorphous silicon layer. After the p-type layer has been formed, the diborane flow is stopped to form an intrinsic region. Thereafter, an n-type dopant, such as phosphine (PH₃), is added to the silane flow in order to form an n-type amorphous silicon layer. The p-i interface can be amorphous silicon carbon containing perhaps 5% carbon at the edge of the p-layer.

Plate 202 (FIGS. 2A and 2B) can be made of, opaque glass, translucent glass, transparent glass and the like. First contact 210 can be a multi-layer structure that includes a transparent metallic oxide layer, a dielectric later and optionally additional layers. Typically, materials of first contact layer 210 are doped.

When first contact 210 is a multi-layer structure, a dielectric outer front layer can be silicon dioxide positioned upon and abutting against an inner surface of plate 202 and a transparent metallic conductive oxide rear layer provides a wide band gap front semiconductor, positioned upon, adjacent and abutting against the dielectric layer. Examples of materials for this rear layer of first contact 210 include but are not limited to, tin oxide, indium-tin oxide, zinc oxide, cadmium stannate and the like. The dielectric layer can be deposited by atmospheric pressure chemical vapor deposition (APCVD), low pressure chemical vapor deposition (LPCVD), or other methods.

Second contact 230 can also be a multi layered structure that includes a metal such as aluminum, silver alloys thereof, and the like. Suitable materials for second contact 230 include but are not limited to a doped material selected from, tin oxide, zinc oxide, indium-tin-oxide, cadmium stannate and the like. In one embodiment, when second contact 230 is a multi-layered structure, an inner front layer can be the metallic conductive oxide and a back layer can be a metal including but not limited to, silver, molybdenum, platinum, steel, iron, niobium, titanium, chromium, bismuth, antimony, aluminum and the like. The inner front layer can be deposited by sputtering, low pressure chemical vapor deposition (LPCVD), spray coating or other methods. The outer metallic layer can be deposited by sputtering or other methods.

In another embodiment, illustrated in FIG. 3B, IGU 100 has a tandem junction cell semiconductor. In this embodiment, first cell 304 and second cell 306 have p₁i₁n₁ and p₂i₂n₂ layers respectively. First cell 304 includes a n-layer 312, an i-layer 322, and a p-layer 332. Second cell 306 includes a n-layer 314, an i-layer 324, and a p-layer 334. The cells increase in thickness from first contact 210 to second contact 230. In yet another embodiment, IGU can have a triple junction cell that includes a third cell with p₃i₃n₃, and often have a larger thickness than the first and second cells.

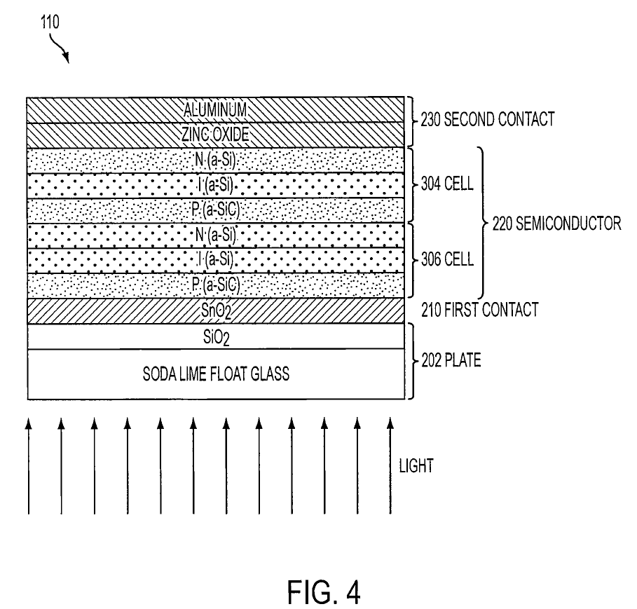

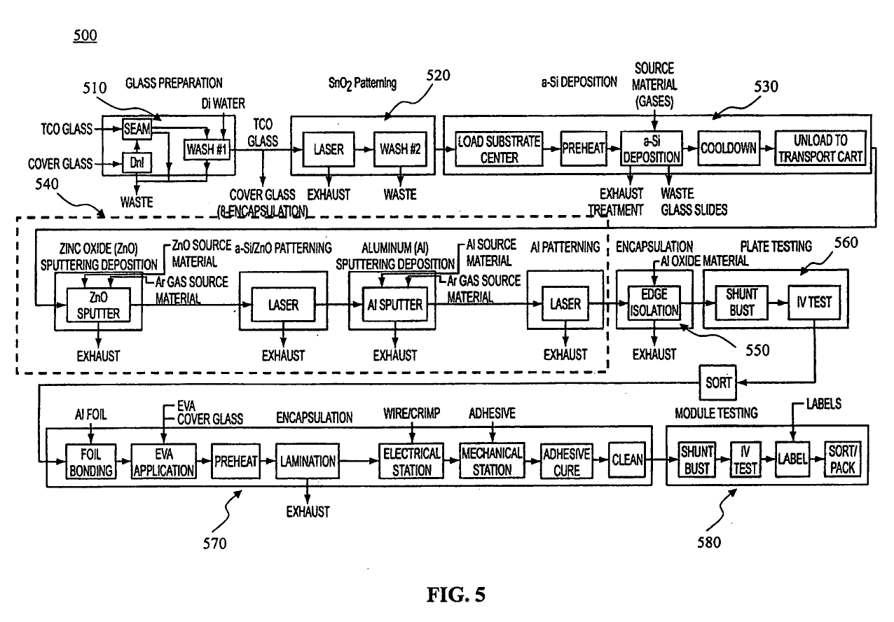

In one specific embodiment, as illustrated in FIG. 4, PV module 110 includes the following, a soda lime float glass plate 202 with SiO₂, an SnO₂ front contact 220, and a tandem junction with the following p₁i₁n₁/p₂i₂n₂ layers: a-SIC:B, a-Si, a-Si:P, a-SiC:B, a-Si and a-Si:P. ZnO is deposited on the last semiconductor layer, followed by deposition of aluminum which is second contact 230.

FIG. 5 illustrates an exemplary procedure 500 for producing IGU 100 according to one embodiment of the invention. Referring now to FIG. 5, in one embodiment of the present invention, a substrate such as plate 202 already has first contact 210 on it. In step 510, plate 202, with first contact 210, is received at a plate preparation station where it is washed to remove particulates, debris and to assure good adhesion. Plate 202 and first contact 210 are washed in a commercial glass washing system using an aqueous soap solution heated 40 to 70 degrees Celsius, and rinsed using deionized water. A laser is used to scribe the deposited SnO₂ layer, followed by a wash step to remove debris from the laser patterning in step 520.

The substrates are then loaded onto a substrate carrier and are preheated to a temperature in the range of 140 to 220 degrees Celsius. The different semiconductor layers are then deposited from the gaseous source materials, including silane, hydrogen, trimethylboron, methane, and phosphine in step 530. The deposition occurs in the temperature range of 140 to 220 degrees Celsius to form a hydrogenated amorphous-silicon tandem junction cell, p₁i₁n₁/p₂i₂n₂, with the following layers: a-SIC:B, a-Si, a-Si:P, a-SiC:B, a-Si and a-Si:P. The substrates, with the semiconductor layers, are then cooled down, and unloaded to a transport cart. The second contact is then deposited on the semiconductor layers in step 540. In one embodiment, ZnO is then sputter deposited onto the semiconductor layers. During a second laser scribing step, the semiconductor and ZnO is patterned. The aluminum second contact is then deposited by sputtering. During a third scribing/patterning step, the aluminum is scribed. Following the patterning step of the aluminum, the edge of PV module 110 is encapsulated in step 550 followed by a plate testing step 560. This is then followed by step 570, including foil bonding, EVA application, preheating and lamination. Wire/crimps are completed at an electrical station, followed by the application of an adhesive at a mechanical station, adhesive curing and then cleaning in step 570. In step 580, the final module is tested.

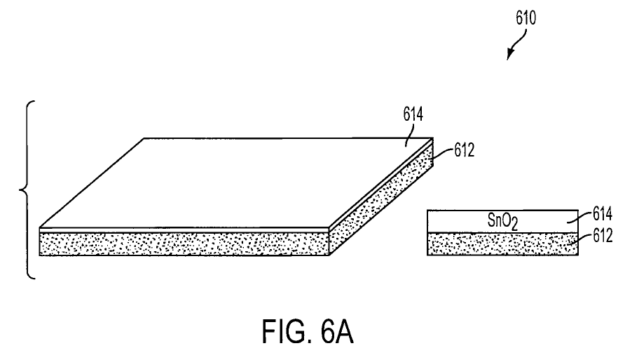

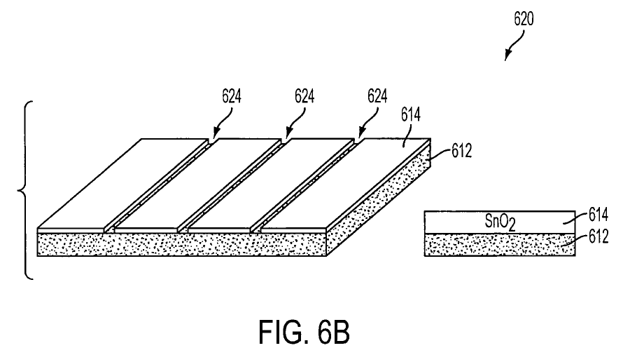

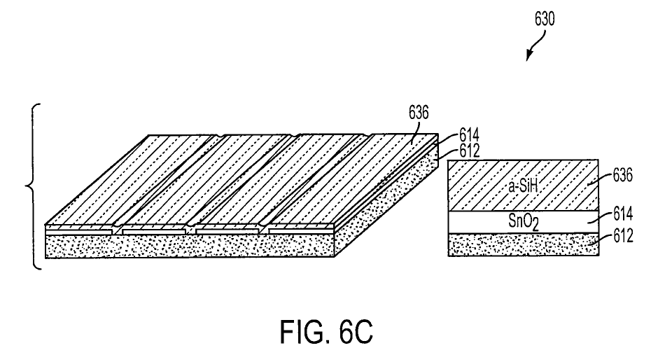

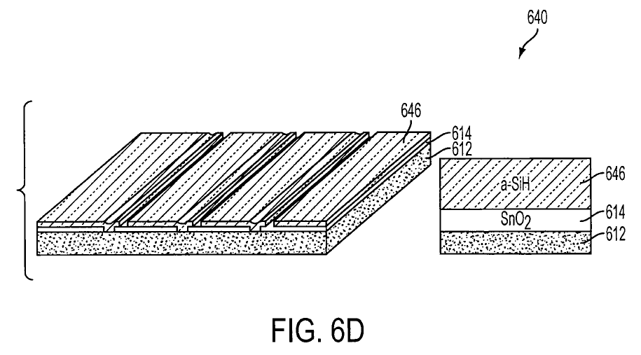

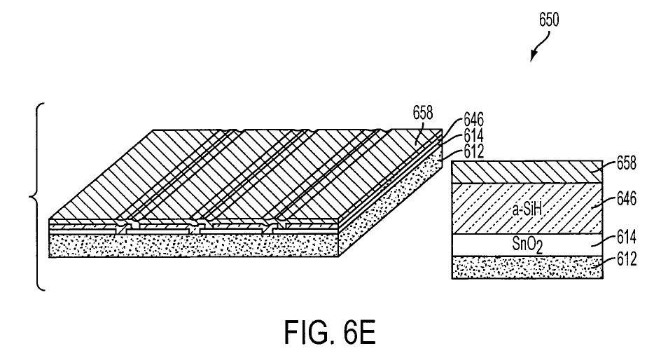

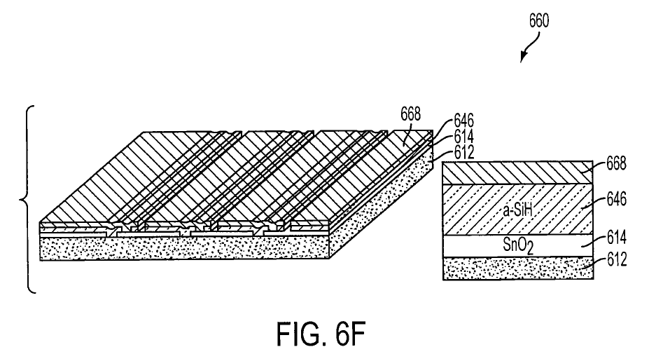

The three laser scribing steps are more fully illustrated in FIGS. 6a through 6f.

### EXAMPLE 1

In this example, an IGU 100 is made with a soda lime float glass as plate 202. This type of plate 202 provides support for the semiconductor. In one embodiment, the plate 202 is initially cleaned in an in-line industrial glass washer.

A thin film layer of SiO₂ is deposited onto one side of the cleaned plate 202. The SiO₂ keeps contaminants in plate 202 from migrating into the semiconductor layers. In addition, the SiO₂ layer acts to smooth out and reduce structural peaks and valleys in plate 202. In this embodiment, the SiO₂ layer is a buffer or barrier layer. The SiO₂ is transparent to allow the light photons to enter into the energy conversion part of the IGU 100. This layer can be deposited when the glass is being manufactured, and can be purchased as a component of the soda lime float glass. In one embodiment as illustrated in FIG. 6a, plate 202 and the thin film layer of SiO₂ form a glass 612.

An SnO₂ layer is deposited onto the SiO₂ film to create a transparent conductive contact for the solar cell. As illustrated in FIG. 6a, a layer of SnO₂ 614 is placed on glass 612. This layer can be deposited when the glass is being manufactured. The SnO₂ layer 614 has the characteristic of allowing about 70-90% of incident light to be transmitted into the energy conversion layers of the semiconductor, while also acting as an electrode to collect current flow, and is a transparent metallic oxide conductive electrode. The SnO₂ has a conductivity of about 5 to 15 ohms/square. This layer can be purchased as a component of the soda lime float glass.

In this embodiment, the cells of the IGU 100 are interconnected with three laser scribing steps. High-powered industrial lasers are used to remove or ablate very thin strips of each of the thin-film materials (SiO₂ does not require this manufacturing step). Three laser scribing steps are employed. The number of scribes and the distance between the ablation strips, or laser scribes, dictates the voltage and current characteristics. In this way, modules of varying voltage for different applications are produced. In successive thin film layers, the laser ablation process is used for laser patterning of those materials. This laser scribing process creates the lines that are seen on thin-film silicon IGUs. The laser scribing process creates lines 624 on SnO₂ layer 614, as shown in FIG. 6b.

A vacuum based plasma-enhanced chemical vapor thin-film deposition system is used to chemically vapor deposit hydrogenated amorphous silicon semiconductor layers 220. Three initial layers act as the p-i-n semiconductor junction. A second p-i-n junction is then deposited on the device to enhance the performance of the module. These semiconductor layers are deposited from gaseous source materials, including silane, hydrogen, trimethylboron, methane, and phosphine. The deposition occurs in the temperature range of 140 to 220 degrees Celsius to form a hydrogenated amorphous-silicon tandem junction cell, p₁i₁n₁/p₂i₂n₂. This process is illustrated in FIGS. 6c and 6d. The tandem junction cell, p₁iₙ/p₂i₂n₂ is illustrated as layer 636 in FIG. 6c and layer 646 in FIG. 6d after the laser scribing process. When sunlight enters into this material, the light energy excites the silicon material, thereby creating a current flow. The conductive SnO₂ and succeeding ZnO and aluminum layers then act as the positive and negative electrodes. One example is shown in FIG. 6e. The four layers in FIG. 6e include a glass layer 612, a SnO₂ layer 614, a tandem junction cell layer 646, and an aluminum layer 658.

As previously mentioned, this material is patterned with the use of the laser material ablation system, as shown in FIG. 6f, where a laser is used to scribe the deposited aluminum layer to form a scribed aluminum layer 668.

A thin layer of highly reflective ZnO is deposited onto the second silicon p-i-n layer using a physical vapor sputter deposition process. The ZnO layer is highly reflective, so that any sunlight that passes through the semiconductor layers that is not converted to electricity is reflected back into the silicon layer for another opportunity for energy conversion.

A pre-heat station is provided to pre-heat the glass/EVA/glass sandwich prior to the insertion of the sandwich into a vacuum laminator.

A mini-junction device 180 is positioned adjacent to a periphery of substrate 150 without extending beyond the periphery. The mini-junction device 180 has wire leads that are ultrasonically bonded to metallic foil strips that act as the positive and negative connections for the IGU 100. The mini-junction device 180 is placed such that the wire leads that protrude from mini-junction device 180 are in close proximity to the edge of substrate 150. The placement of mini-junction device 180 is preferentially located in a position that minimizes interference with an exterior frame while also providing an aesthetically desirable appearance. Mini-junction device 180 is attached to the surface of substrate 150 with an electrically-insulating structural adhesive.

### EXAMPLE 2

In this example, a similar process as in Example 1 is followed. In this example, first contact 210 is a multi-layer structure of silicon dioxide positioned upon and abutting against the inner surface of plate 202 and zinc oxide deposited by low pressure chemical vapor deposition (LPCVD). Second contact 230 is a multi layered structure that includes a silver alloy and doped indium-tin-oxide.

### EXAMPLE 3

In this example, a similar process as in Example 1 is followed. In this example, the semiconductor is hydrogenated amorphous silicon carbon. In this example, a similar process as in Example 1 is followed, except that the semiconductor is hydrogenated amorphous silicon carbon. A carbon containing gas, such as methane, is introduced into the reactor during the a-Si deposition process to incorporate carbon into some or all of the amorphous silicon layers.

### EXAMPLE 4

In this example, the semiconductor is copper-indium-gallium-diselenide (Culnₓ Ga₁₋ₓ Se₂). Copper is deposited onto second contact 230 while the substrate is at about 275° C. Gallium is then deposited onto the deposited copper. Indium is deposited in the presence of a selenium flux onto the deposited gallium while the substrate is at about 275° C. Copper is then deposited onto the indium in the presence of a selenium flux while the substrate is at about 275° C., followed by deposition of gallium and then indium in the presence of a selenium flux onto the deposited gallium while the substrate is at about 275° C. The structure is then heated in the presence of a selenium flux to a temperature substantially higher than 275° C.

### EXAMPLE 5

In this example, a CdTe/CdS IGU is made as follows. An n-type CdS film layer is deposited by vacuum evaporation at a substrate temperature of 350° C. A p-type CdTe layer is formed by vacuum evaporation at a substrate temperature 350° C. The p-type CdTe layer is dipped in a methanol solution containing copper chloride (CuCl₂) or a CH.3 OH solution containing CuCl₂ and CdCl₂. It is then dried by natural drying and annealed at 400° C. for 15 minutes in an N₂+O₂ (4:1) atmosphere. A surface of the CdTe layer is etched using a K₂ Cr₂ O₇+H₂ SO₄ +H₂ 0 solution. Cu (10 nm)/Au (100 nm) is then deposited by vacuum evaporation and then annealed at 150° C. for about three hours.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. Expected variations or differences in the results are contemplated in accordance with the objects and practices of the present invention. It is intended, therefore, that the invention be defined by the scope of the claims which follow and that such claims be interpreted as broadly as is reasonable.

1. A solar panel, comprising:
an insulating glass unit, wherein the insulating glass unit comprises:
a first substrate;
a second substrate substantially parallel to and spaced apart from the first substrate, wherein the first and second substrates are hermetically sealed;
a mini-junction device positioned between and at an edge of the first and second substrates without extending beyond a periphery of the first and second substrates, wherein the mini-junction device houses an electrical coupling between a first end of a pair of wires and a first end of a pair of leads, and wherein a second end of the pair of wires extends beyond the periphery of the substrates, and a second end of the pair of leads extends through the first substrate; and
a photovoltaic module coupled to the first substrate and electrically coupled to the second end of the pair of leads.

2. The solar panel of claim 1, wherein the photovoltaic module comprises:
a plate;
a first contact coupled to the plate;
a semiconductor coupled to the first contact;
a second contact coupled to the semiconductor and coupled to the second end of the pair of leads;
an interconnect formed between the first and second contacts; and
an encapsulant positioned to environmentally seal the photovoltaic module, wherein the encapsulant includes an aperture with the pair of leads extending from the aperture.

3. The solar panel of claim 2, wherein the semiconductor comprises one or more p-i-n junction cells, wherein each of the p-i-n junction cells comprises:
a positively doped (p-doped) amorphous silicon layer;
an undoped intrinsic amorphous silicon layer; and
a negatively doped (n-doped) amorphous silicon layer.

4. The solar panel of claim 2, wherein the semiconductor has an etching formed by the removal of one or more portions of the semiconductor to create regions of partial transparency.

5. The solar panel of claim 1, further comprising an exterior frame defining the exterior perimeter of the solar panel, wherein the insulating glass unit is positioned within the exterior frame.

6. The solar panel of claim 1, wherein the mini-junction device satisfies the requirements specified in UL 1703.

7. The solar panel of claim 1, wherein the mini-junction device has a low profile that is less than a pre-selected value.

8. The solar panel of claim 1, further comprising an electrical power unit coupled to the second end of the pair of wires to output electricity generated by the photovoltaic module.

9. A solar panel, comprising:
an array of insulating glass units, wherein each insulating glass unit comprises:
a first substrate;
a second substrate substantially parallel to and spaced apart from the first substrate, wherein the first and second substrates are hermetically sealed;
a mini-junction device positioned between and at an edge of the first and second substrates without extending beyond a periphery of the first and second substrates, wherein the mini-junction device houses an electrical coupling between a first end of a pair of wires and a first end of a pair of leads, and wherein a second end of the pair of wires extends beyond the periphery of the substrates, and a second end of the pair of leads extends through the first substrate; and
a photovoltaic module coupled to the first substrate and electrically coupled to the second end of the pair of leads; and
an exterior frame defining the exterior perimeter of the solar panel, wherein the array of insulating glass units are positioned within the exterior frame.

10. The solar panel of claim 9, wherein the photovoltaic module comprises:
a plate;
a first contact coupled to the plate;
a semiconductor coupled to the first contact;
a second contact coupled to the semiconductor and coupled to the second end of the pair of leads;
an interconnect formed between the first and second contacts; and
an encapsulant positioned to environmentally seal the photovoltaic module, wherein the encapsulant includes an aperture with the pair of leads extending from the aperture.

11. The solar panel of claim 10, wherein the semiconductor comprises one or more p-i-n junction cells, wherein each of the p-i-n junction cells comprises:
a positively doped (p-doped) amorphous silicon layer;
an undoped intrinsic amorphous silicon layer; and
a negatively doped (n-doped) amorphous silicon layer.

12. The solar panel of claim 10, wherein the semiconductor has an etching formed by the removal of one or more portions of the semiconductor to create regions of partial transparency.

13. The solar panel of claim 9, wherein the mini-junction device satisfies the requirements specified in UL 1703.

14. The solar panel of claim 9, wherein the mini-junction device has a low profile that is less than a pre-selected value.

15. The solar panel of claim 9, further comprising an electrical power unit coupled to the second end of the pair of wires to output electricity generated by the photovoltaic module.

16. An insulating glass unit, comprising:
a first substrate;
a second substrate substantially parallel to and spaced apart from the first substrate, wherein the first and second substrates are hermetically sealed;
a mini-junction device positioned between and at an edge of the first and second substrates without extending beyond a periphery of the first and second substrates, wherein the mini-junction device houses an electrical coupling between a first end of a pair of wires and a first end of a pair of leads, and wherein a second end of the pair of wires extends beyond the periphery of the substrates, and a second end of the pair of leads extends through the first substrate; and
a photovoltaic module coupled to the first substrate and electrically coupled to the second end of the pair of leads.

17. The insulating glass unit of claim 16, wherein the photovoltaic module comprises:
a plate;
a first contact coupled to the plate;
a semiconductor coupled to the first contact;
a second contact coupled to the semiconductor and coupled to the second end of the pair of leads;
an interconnect formed between the first and second contacts; and
an encapsulant positioned to environmentally seal the photovoltaic module, wherein the encapsulant includes an aperture with the pair of leads extending from the aperture.

18. The insulating glass unit of claim 17, wherein the semiconductor comprises one or more p-i-n junction cells, wherein each of the p-i-n junction cells comprises:
a positively doped (p-doped) amorphous silicon layer;
an undoped intrinsic amorphous silicon layer; and
a negatively doped (n-doped) amorphous silicon layer.

19. The insulating glass unit of claim 17, wherein the semiconductor has an etching formed by the removal of one or more portions of the semiconductor to create regions of partial transparency.

20. The insulating glass unit of claim 16, wherein the mini-junction device satisfies the requirements specified in UL 1703.

21. The insulating glass unit of claim 16, wherein the mini-junction device has a low profile that is less than a pre-selected value.
